(19) United States
(12) Patent Application Publication
(10) Pub. No.: US 2010/0238536 A1
(43) Pub. Date: Sep. 23, 2010

(54) INTEGRATED SILICON/SILICON-GERMANIUM MAGNETO-OPTIC ISOLATOR

(76) Inventors: Juejun Hu, Cambridge, MA (US); Lei Bi, Cambridge, MA (US); Lionel C. Kimerling, Concord, MA (US); Gerald F. Dionne, Winchester, MA (US); Caroline A. Ross, Arlington, MA (US)

Correspondence Address: GAUTHIER & CONNORS, LLP, 225 FRANKLIN STREET, SUITE 2300, BOSTON, MA, 02110, US

(21) Appl. No.: 12/406,313

(22) Filed: Mar. 18, 2009

(51) Int. Cl. G02F 1/09; H01L 21/00; G02B 6/42

(52) U.S. Cl. 359/280; 438/3; 257/E21.02; 385/32

(57) ABSTRACT

A magneto-optical isolator device is provided. The isolator device includes a substrate and a bottom cladding layer that is formed on the substrate. An optical resonator structure is formed on the bottom cladding layer. The resonator structure includes crystalline or amorphous diamagnetic silicon or silicon-germanium so as to provide non-reciprocal optical isolation. A top cladding layer is formed on the resonator structure. One or more magnetic layers positioned on the top cladding layer or between the top cladding or bottom cladding layers and the optical resonator structure.

### BACKGROUND OF THE INVENTION

The invention is related to microphotonics, and in particular to designs of planar-integrated optical isolators using silicon material.

Integrated optical isolators, namely the devices that allow the transmission of light in only one direction, are necessary to prevent unwanted reflection back into the laser, and are thus an important component in integrated photonic systems. Optical isolation, for example, unidirectional transmission is typically realized by means of nonreciprocal magneto-optical effects of ferromagnetic materials such as Faraday rotation and nonreciprocal phase shift. However, most ferromagnetic materials have lattice constants different from that of silicon and therefore cannot be monolithically grown on a silicon substrate; in addition, ferromagnetic materials are often comprised of ferro-metallic alloys, exotic oxides or semiconductors doped with transition metal ions, none of which is compatible with the standard silicon CMOS fabrication process due to contamination issues.

Because of such incompatibilities, currently magneto-optic isolators are made in bulk garnet-based materials. Such bulk isolators are not amenable to planar integration and their cost is also high since optical-quality crystals are required to maximize the desired magneto-optic effect. Recently, magneto-optic isolator devices employing hybrid architecture have been demonstrated, in which magnetically active garnet materials are bonded onto a silicon substrate. Compared to such a hybrid design, a monolithic solution requires simpler equipment, is less demanding in terms of fabrication and more cost effective, and is thus a more attractive approach. In summary, optical isolators that can be monolithically integrated onto a silicon platform have been highly desirable but still remain to be developed.

### SUMMARY OF THE INVENTION

According to one aspect of the invention, there is provided a magneto-optical isolator device. The isolator device includes a substrate and a bottom cladding layer that is formed on the substrate. An optical resonator structure is formed on the bottom cladding layer. The resonator structure includes crystalline or amorphous diamagnetic silicon or silicon-germanium so as to provide non-reciprocal optical isolation. A top cladding layer is formed on the resonator structure. One or more magnetic layers positioned on the top cladding layer or between the top cladding or bottom cladding layers and the optical resonator structure.

According to another aspect of the invention, there is provided a method of forming a magneto-optical isolator device. The method includes providing a substrate forming a bottom cladding layer on the substrate and positioning an optical resonator structure on the bottom cladding layer. The resonator structure includes crystalline or amorphous diamagnetic silicon or silicon-germanium so as to provide non-reciprocal optical isolation. Also, the method includes forming a top cladding layer on the resonator structure. Furthermore, the method includes positioning one or more magnetic layers on the top cladding layer or between the top cladding or bottom cladding layers and the optical resonator structure.

### BRIEF DESCRIPTION OF THE DRAWINGS

FIG. 1 is a schematic diagram illustrating the inventive magneto-optic isolator device incorporating a resonator structure;

FIGS. 2A-2D are schematic diagrams illustrating the cross-sectional view of the resonator structure of FIG. 1;

FIG. 3 is a graph illustrating the transmission spectra of a magnetically active Si/SiGe resonator;

FIG. 4 is a schematic diagram illustrating an inventive isolator device, having an input and an output waveguides coupled to a Si/SiGe non-reciprocal resonator.

### DETAILED DESCRIPTION OF THE INVENTION

The invention provides optical isolator designs using silicon/silicon-germanium materials to achieve very low manufacturing cost, compatibility with planar microphotonic integration and possibly scalable performance improvement. In one example, the invention provides an optical waveguide coupled to a planar optical resonator made of silicon on insulator (SOI) material or silicon-germanium alloy grown on silicon and in the form of micro-ring, micro-disk or micro-racetrack.

An in-plane magnetic field is applied by patterned permanent ferromagnetic films on both sides of the waveguides comprising the resonator. The diamagnetic nature of silicon/silicon-germanium leads to nonreciprocal phase shift in the SOI waveguides, which lifts the degeneracy of counter-propagating resonant modes in the resonator. The operating wavelength of the device is specifically chosen to be resonant with backward propagating waves in the resonator; therefore, the back-reflected light is coupled into the resonator and dissipated while the forward-propagating light remains unaffected by the resonator and hence leads to an optical isolation effect. In another example, the isolator device includes a silicon/silicon-germanium resonator coupled to two optical waveguides, as well as magnetic films to provide magnetization in silicon. The operating wavelength is chosen so that the forward-propagating wave is resonant in the resonator: light from the laser can thus be coupled into the resonator and then coupled into the other waveguide as the output, whereas reflected light remains in one waveguide and cannot be fed back into the laser.

Silicon is a diamagnetic material and thus has traditionally been regarded as non-magnetically active. However, the fact that silicon has very low optical loss in the 1310 and 1550 nm telecommunication bands has been overlooked for optical isolator applications. The measurement has yielded Verdet constant of doped and undoped single crystalline silicon in the range of 12-17 deg/(T·cm) at 1550 nm wavelength. Further, the Verdet constant of silicon at 1310 and 1550 nm bands can be further improved by addition of germanium to form silicon-germanium alloys. Since silicon-germanium alloys can be monolithically grown on silicon substrate, such compatibility offers significant competitive edge for cost reduction and process improvement over current bulk magneto-optic device.

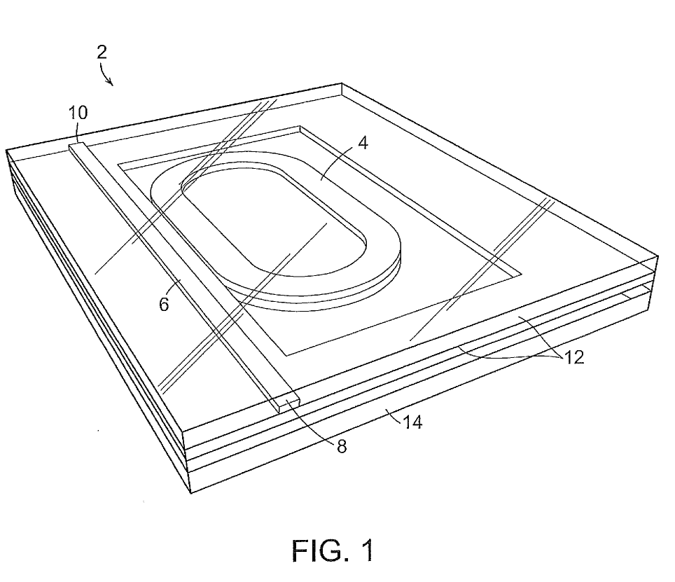

An inventive magneto-optic isolator device 2 incorporating a resonator structure 4 is schematically shown in FIG. 1. It comprises of an optical waveguide 6 for light input 8 and output 10, as well as a magnetically active optical resonator 4 having silicon/silicon-germanium materials, coupled to the optical waveguide 6, and top and bottom cladding layers 12 that formed on a substrate 14. In this figure, a racetrack resonator 4 has been used as an example; however, the same function can be performed with other device geometries including micro-ring and micro-disk resonators. Moreover, the isolator device 2 can include Lore than one optical waveguide.

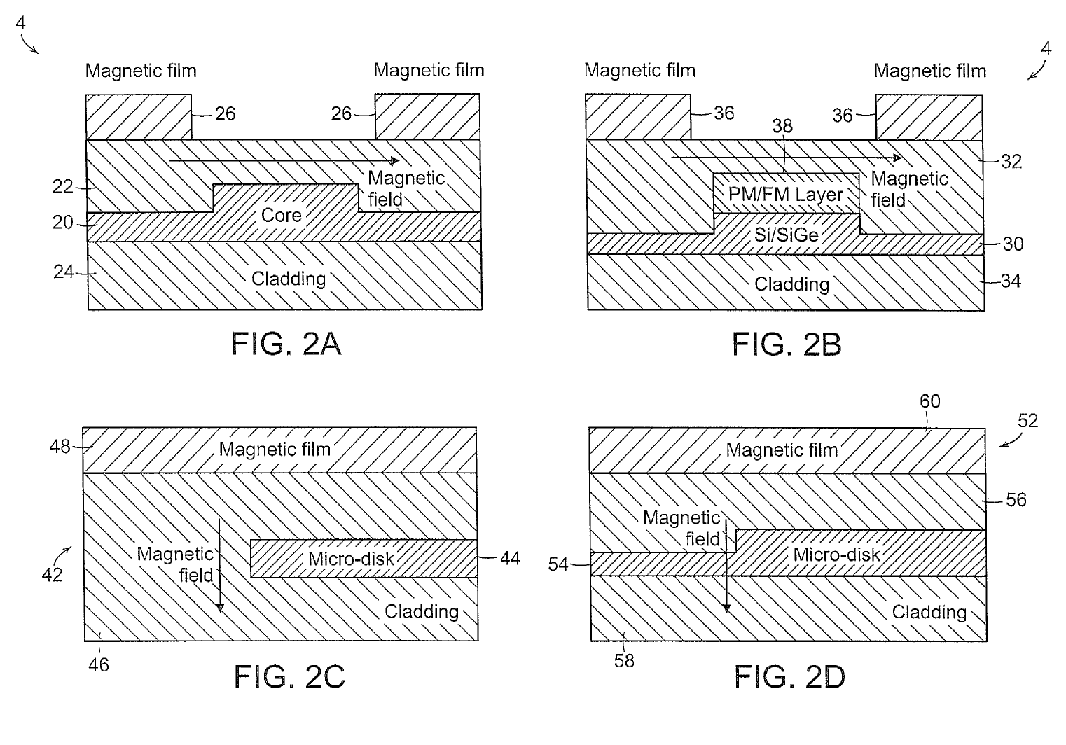

FIGS. 2A-2D show the cross-sectional view of the resonator 4. In particular, FIG. 2A shows the resonator 4 having a single layer rib/ridge waveguide design having a waveguide core 20 comprising of silicon/silicon-germanium, a top cladding 22, bottom cladding 24, and magnetic films 26 deposited over the top cladding 22. The top 22 and bottom cladding layers encompasses the waveguide core. Also, the top and bottom cladding 24 layers comprise similar materials. FIG. 2B shows another design for resonator 4 comprising a rib/ridge waveguide structure having a multi-layer design having a waveguide core 30, a top cladding layer 32, a bottom cladding layer 34, and magnetic films 36 positioned on the top cladding layer 32. One or more ferromagnetic or paramagnetic layers 38 are sandwiched between the resonator structure and the top cladding layer 32 so as to increase the magneto-optical effect in the resonator to enhance the non-reciprocal phase shift in the resonator 4. The one or more ferromagnetic or paramagnetic layers can include oxide glasses, chalcogenide glasses, oxide crystals, or transition metal ion doped semiconductor materials. The top 32 and bottom 34 cladding layers encompass the waveguide core 30.

FIG. 2C shows an isolator device 42 having a micro-disk resonator structure 44 comprising silicon/silicon-germanium, a single cladding layer 46, and a continuous magnetic film layer 48 positioned on the single cladding layer 46. Note in FIG. 2C there is no formation of a top and bottom cladding layers but a single cladding layer 46. The single cladding layer 46 totally encompasses the micro-disk resonator structure 44. FIG. 2D shows an isolator device 52 having a micro-disk resonator structure 54 comprising silicon/silicon-germanium, a top cladding layer 56, a bottom cladding layer 58, and a continuous magnetic film layer 60 positioned on the top cladding structure. The top 56 and bottom 58 cladding layer totally encompass a silicon/silicon-germanium micro-disk resonator structure 54. The isolator structure 4 shown in FIGS. 2A and 2B can be used for TE polarization, and the isolator structure 42, 52 shown in FIGS. 2C and 2D can be used for TM polarization.

The top and bottom cladding layers described in FIGS. 2A-2D can include SiOx, SiN_{X} or polymer. Also, the magnetic layers described in FIGS. 2A-2D can include ferromagnetic metals, rare earth ferromagnetic metal alloys, or micro electromagnets.

Magnetic field applied using patterned magnetic films leads to magnetization in the Si/SiGe waveguide core. If the isolator device is designed for transverse magnetic (TM) polarization, the top and bottom cladding layers can include patterned magnetic films being placed on both sides of the waveguide core, providing an in-plane magnetic field perpendicular to the light propagation direction. Alternatively, if the isolator device operates with transverse electric (TE) polarization, a continuous magnetic film layer can be deposited on top of the waveguide structure to yield a magnetic field perpendicular to the substrate. The inherent structural asymmetry in the rib/ridge structure can thus produce non-reciprocal phase shift for TM polarized light. In a microdisk resonator, similar rib/ridge structures can be used for TM polarization; the in-plane structural asymmetry of a micro-disk also allows micro-disk isolator operation with TE polarized light.

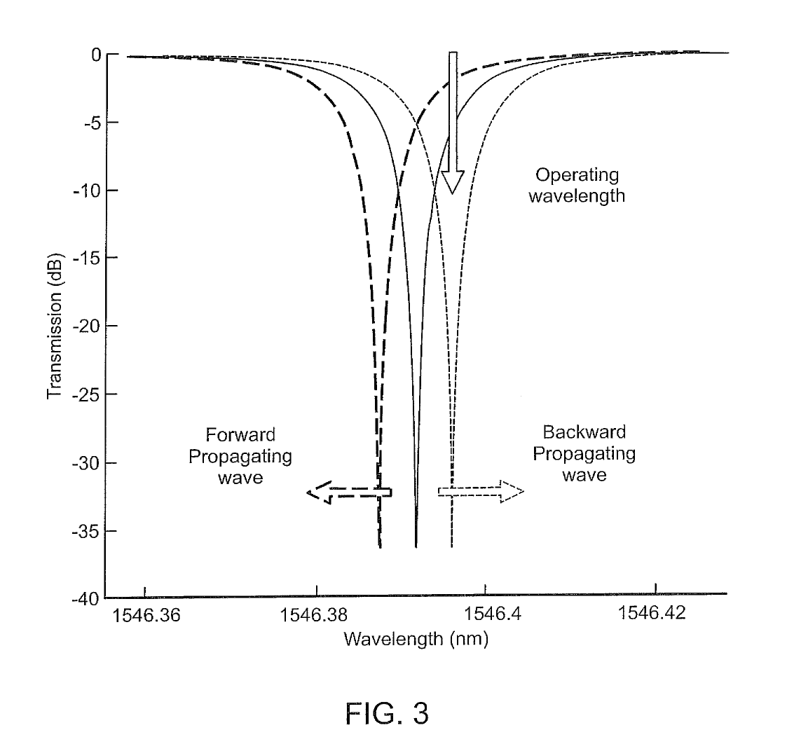

The resonant frequency degeneracy of light propagating in clockwise, corresponding to forward-propagating wave in FIG. 1, and counter-clockwise, corresponding to backward-propagating wave in FIG. 1, directions is broken. If the operating wavelength is chosen so as to match the resonant wavelength of backward propagating wave, backward propagating light due to reflection or scattering will couple into the resonator and radiatively dissipated, while the forward propagation signal will hardly be affected providing that the peak separation is greater than the peak width. FIG. 3 shows numerically simulated transmission spectra for a nonreciprocal SiGe resonator isolator device operating at −1550 nm wavelength.

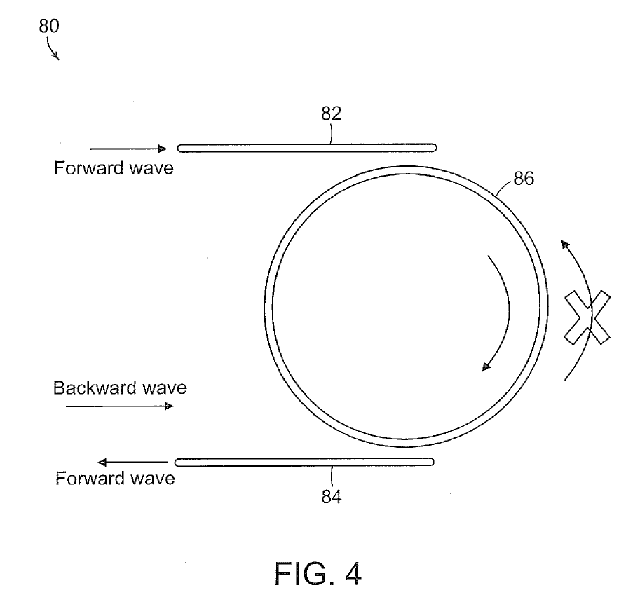

In another embodiment, the isolator device 80 includes of two optical waveguides, one for optical input 82 and one for output 84, both coupled to a Si/SiGe micro-resonator 86, as is illustrated in FIG. 4. Light propagating in the resonator 86 experiences a non-reciprocal phase shift when a magnetic field is applied to the Si/SiGe material. The operating wavelength is chosen to be the resonant wavelength of the forward propagating wave, and therefore optical isolation of back-reflected light is achieved since light transfer from the output waveguide 84 to the input waveguide 82 does not satisfy the resonant condition and thus is prohibited.

In embodiments described herein, high isolation ratio in a Si/SiGe resonator isolator device can be achieved by: 1) minimized peak full-width-at-half-maximum (FWHM) of the resonant peak; and 2) large resonant peak separation between forward and backward propagating waves. The peak width is inversely proportional to optical propagation loss in the resonator. Both crystalline and hydrogenated amorphous silicon exhibit optical loss in the telecommunication wavebands as low as a few dB/cm (<1 dB/cm for single crystalline Si). The optical band gap of silicon-germanium alloys can be continuously tuned from 1.1 eV to 0.7 eV by adjusting the alloy composition, and low optical absorption loss at telecommunication bands can be achieve in Si-rich SiGe alloys, suitable for isolator application.

The peak separation is related to the propagation phase shift in the waveguiding structure, which is determined by the Verdet constant of the waveguide materials and the asymmetry of the optical guiding mode. The Verdet constant is correlated to the refractive index dispersion by the well-known Becquerel formula:

$$V = \frac{e}{2 {mc}^{2}} λ \cdot ( \frac{d n}{d λ} ) \qquad ( 1 )$$

Alloying silicon with germanium increases the material dispersion at telecommunication wavelengths, and thereby the SiGe Verdet constant can be increased. Multilayer guiding structures with ferromagnetic or paramagnetic overlayers, such as oxide crystals including garnets, perovskites or spinels, transition metal ion doped semiconductors, oxide or chalcogenide glasses, with Faraday rotation or Verdet constant of sign opposite to that of Si/SiGe can be used to enhance the resonant modal asymmetry in the optical resonator 4, as is schematically shown in FIG. 2B.

Although the present invention has been shown and described with respect to several preferred embodiments thereof, various changes, omissions and additions to the form and detail thereof, may be made therein, without departing from the spirit and scope of the invention.

What is claimed is:

1. A magneto-optical isolator device comprising:
a substrate;
a bottom cladding layer formed on said substrate;
an optical resonator structure that is formed on said bottom cladding layer, said resonator structure comprising crystalline or amorphous diamagnetic silicon or silicon-germanium so as to provide non-reciprocal optical isolation;
a top cladding layer formed on said resonator structure; and
one or more layers positioned on said top cladding layer or between said top cladding or bottom cladding layers and said optical resonator structure so as to produce non-reciprocal phase shift for TM polarized light

2. The isolator device of claim 1, wherein said resonator structure comprises a micro-ring resonator coupled to one or two optical waveguides.

3. The isolator device of claim 1, wherein said resonator structure comprises a micro-disk resonator coupled to one or more optical waveguides.

4. The isolator device of claim 1, said substrate comprises silicon.

5. The isolator device of claim 1 further comprising one or more ferromagnetic or paramagnetic layers being positioned between said optical resonator structure and said top cladding layer so as to increase the magneto-optical effect in the resonator.

6. The isolator device of claim 1, wherein said one or more ferromagnetic or paramagnetic layers comprise oxide glasses, chalcogenide glasses, oxide crystals, or transition metal ion doped semiconductor materials.

7. The isolator device of claim 1, wherein said bottom cladding layer comprises SiOx, SiNₓ or polymer.

8. The isolator device of claim 1, wherein said top cladding layer comprises SiOₓ, SiNₓ or polymer.

9. The isolator device of claim 1, wherein said one or more layers comprise ferromagnetic metals, rare earth ferromagnetic metal alloys, or micro electromagnets.

10. The isolator device of claim 1, wherein said one or more layers are patterned so as to provide designed magnetic field intensity and distribution in the said resonator structure.

11. A method of forming a magneto-optical isolator device comprising:
providing a substrate;
forming a bottom cladding layer on said substrate;
positioning an optical resonator structure on said bottom cladding layer, said resonator structure comprises crystalline or amorphous diamagnetic silicon or silicon-germanium so as to provide non-reciprocal optical isolation;
forming a top cladding layer on said resonator structure; and
positioning one or more layers on said top cladding layer or between said top cladding or bottom cladding layers and said optical resonator structure so as to produce non-reciprocal phase shift for TM polarized light

12. The method of claim 11, wherein said resonator structure comprises a micro-ring resonator coupled to one or two optical waveguides

13. The method of claim 11, wherein said resonator structure comprises a micro-disk resonator coupled to one or more optical waveguides.

14. The method of claim 11 further comprising positioning one or more ferromagnetic or paramagnetic layers between said optical resonator structure and said top cladding layer so as to increase the magneto-optical effect in the resonator.

15. The method of claim 11, wherein said substrate comprises silicon.

16. The method of claim 11, wherein said one or more ferromagnetic or paramagnetic layers comprise oxide glasses, chalcogenide glasses, oxide crystals, or transition metal ion doped semiconductor materials.

17. The method of claim 11, wherein said bottom cladding layer comprises SiOₓ, SiNₓ or polymer.

18. The method of claim 11, wherein said top cladding layer comprises SiOₓ, SiNₓ or polymer.

19. The method of claim 11, wherein said one or more layers comprise ferromagnetic metals, rare earth ferromagnetic metal allows, or micro electromagnets.

20. The method of claim 11, wherein said one or more layers are patterned so as to provide designed magnetic field intensity and distribution in the said resonator structure.
